(19) United States
(12) Patent Application Publication
(10) Pub. No.: US 2023/0399744 A1
(43) Pub. Date: Dec. 14, 2023

(54) DEVICE INCLUDING TRANSPARENT POLYMER WITH HYDROPHILIC COATING, AND METHOD OF MAKING SAME

(71) Applicant: AGILENT TECHNOLOGIES, INC., Santa Clara, CA (US)

(72) Inventors: Elizabeth CARR, Santa Clara, CA (US); Frank STRELLER, Santa Clara, CA (US); Li-Chih HU, San Jose, CA (US); David Michael LYNCH, Menlo Park, CA (US); Richard CLOSSER, Mountain View, CA (US)

(73) Assignee: AGILENT TECHNOLOGIES, INC., Santa Clara, CA (US)

(21) Appl. No.: 18/126,948

(22) Filed: Mar. 27, 2023

Related U.S. Application Data
(60) Provisional application No. 63/350,800, filed on Jun. 9, 2022.

(51) Int. Cl. C23C 16/455; C23C 16/40; C23C 16/44; C23C 16/52

(52) U.S. Cl. CPC C23C 16/45542; C23C 16/402; C23C 16/4412; C23C 16/45502; C23C 16/4404; C23C 16/45548; C23C 16/45565; C23C 16/52

(57) ABSTRACT

A device, including a hydrophilic layer on a portion of an inner surface of a transparent polymer forming a body; wherein the hydrophilic layer includes a sulfonated inner surface of the transparent polymer, a silica, a silicon oxycarbide, an O₂ plasma treatment of the transparent polymer, or a combination thereof. The device can be a nebulizer or a spray chamber, for example used in an inductively coupled plasma device. A method of making the device is also disclosed.

### RELATED APPLICATION

The present application claims priority to U.S. Provisional Application No. 63/350,800, filed Jun. 9, 2022, the entire disclosure of which is hereby incorporated by reference.

### FIELD OF THE INVENTION

The present disclosure generally relates to a device including a hydrophilic layer on a portion of an inner surface of a transparent polymer forming a body; wherein the hydrophilic layer includes a sulfonated inner surface of the transparent polymer, a silica, a silicon oxycarbide, an O₂ plasma treatment of the transparent polymer, or a combination thereof. The device can be a nebulizer or a spray chamber, for example used in an inductively coupled plasma device. A method of making the device is also disclosed.

### BACKGROUND OF THE INVENTION

In an Inductively Coupled Plasma Optical Emission Spectrometry (ICP-OES) or Inductively Coupled Plasma Mass Spectrometry (ICP-MS) sample introduction system, a sample enters a nebulizer and is broken up into a fine aerosol by pneumatic action of gas flow dispersing the liquid sample into tiny droplets. This nebulized spray is flowed into a spray chamber along with an inert gas where large and small droplets are separated out. For ICP, monodisperse droplets smaller than 10 μm are ideal, while larger droplets interfere with signal stability and intensity. For this reason, only the smallest droplets are allowed to pass through the spray chamber into the plasma, in order to efficiently atomize and finally ionize the sample's elemental components, thus achieving accurate quantitative analysis. In particular, the droplets are sorted by the design of the spray chamber and the vortex of gas flow, whereby larger droplets collide with the spray chamber walls by means of centrifugal force, leaving behind the smaller droplets to pass further into the plasma where they will be ionized by high temperature and analyzed for their elemental makeup. The larger droplets that bombarded the spray chamber surface seep down the spray chamber walls and out of the flow path so as to not interfere with the finer spray droplets.

To achieve the drainage needed to remove the larger droplets from the spray chamber surface, the surface itself must be able to wick away the solvent. Solvents such as water and alcohols drain away easier if the spray chamber surface is hydrophilic in nature. Glass, which is naturally hydrophilic, is typically used for spray chambers, which allows the drainage needed. Glass is also robust to acids that are used for ICP and is transparent, allowing users to visualize the drainage of the solution that has hit the spray chamber walls. With a hydrophilic surface like glass, the drainage is rapid, owing to less time needed to ‘wash out’ the sample before the next analysis. If the surface begins to become contaminated or loses its hydrophilicity, these wash outs are not sufficient to remove the sample residues and can cause erroneous analysis or excessively long washout times. Over time, glass spray chambers need to be cleaned or replaced, which can become costly for the users. Additionally, the production of glass spray chambers requires manual glass shaping by experienced glass technicians. This is expensive (hundreds of dollars each piece) and somewhat design limited.

Other existing materials for spray chambers, typically for specialized applications (e.g., hydrofluoric acid resistance), include fluorocarbon containing plastics, such as perfluoro-polymers (e.g. perfluoroalkoxy alkane (PFA) or polytetrafluoroethylene (PTFE)), and the inert plastic PEEK. Perfluoro-polymers are generally opaque, which prohibits visual observation of solution spraying and introduction (which is considered important by ICP-OES users). Furthermore, the perfluoro-polymers are hydrophobic, thus an expensive hydrophilic coating must be applied on the inner surface to avoid liquid beading of the spray chamber (which may interfere with the analysis and waste solution drainage).

A cost-friendly solution to manufacturing a high-performance spray chamber is desired.

The shape of glass spray chambers is limited to a combination of pre-formed (molded or extruded) parts plus minor manual modifications performed by glass blow-molding. What is needed is a device that can be cheaply made in a variety of versatile shapes without being labor or cost intensive.

Glass spray chambers will shatter when dropped from a benchtop to a floor. Additionally, glass spray chambers can crack under usage and cleaning conditions. What is needed is a device with a reasonable impact resistance at ambient use conditions. Moreover, the device should be resistant to cracks.

### BRIEF DESCRIPTION OF THE DRAWINGS

Features of the present disclosure are illustrated by way of example and not limited in the following figure(s), in which like numerals indicate like elements, in which:

FIGS. 1A-C illustrate various devices according to aspects of the invention;

FIG. 2 is a graph illustrating the surface hydrophilicity of a sulfonated polystyrene as compared to device without a hydrophilic coating;

FIG. 3A is a picture of an untreated polystyrene coupon in a pseudo spray chamber showing beading of an aerosol;

FIG. 3B is a picture of a sulfonated polystyrene coupon that does not show beading of an aerosol;

FIG. 4 is a graph illustrating the surface hydrophilicity of a sulfonated polystyrene as compared to device without a hydrophilic coating, and after washing with solvents;

FIG. 5A is a picture of plasma-enhanced chemical vapor deposition (PECVD) silica coated polystyrene coupon that was contacted with 20% aqua regia in a pseudo spray chamber showing non-beading of a sprayed solution;

FIG. 5B is picture of PECVD silica coated polystyrene coupon that was contacted with A-solv, followed by sonication, in a pseudo spray chamber showing non-beading of a sprayed solution;

FIG. 5C is picture of an untreated polystyrene coupon in a pseudo spray chamber showing beading of an aerosol;

FIG. 6 is a graph illustrating the surface hydrophilicity (as measured by the static water contact angle) of silica coated polyethylene terephthalate with glycol modification after washing with solvents followed by ultrasonic cleaning in cleaning solutions over a period of time;

FIG. 7A is an optical microscopy image of a PECVD silica coated polyethylene terephthalate glycol (PETG) coupon contacted for 25 days with 20% aqua regia, followed by sonication in 5% Triton X-100 for 5 days;

FIG. 7B is an optical microscopy image of a PECVD silica coated PETG coupon contacted for 25 days with A-solv, followed by sonication in 5% Triton X-100 for 5 days;

FIG. 8 is a graph illustrating the surface hydrophilicity of cyclic olefin polymer with an O₂ plasma treatment (just treated) as compared to device without a hydrophilic coating, and after washing with solvents;

FIG. 9A is an image of an untreated cyclic olefin coupon in a pseudo spray chamber showing beading of an aerosol; and

FIG. 9B is an image with an O₂ plasma treatment coupon in a pseudo spray chamber that does not show beading of an aerosol;

FIG. 10 is a graph illustrating the surface hydrophilicity of polyethylene terephthalate with glycol modification with an O₂ plasma treatment (just treated) as compared to device without a hydrophilic coating, and after washing with solvents;

FIG. 11A is an image of an untreated polyethylene terephthalate with glycol modification coupon in a pseudo spray chamber showing beading of an aerosol;

FIG. 11B is an image with an O₂ plasma treatment coupon in a pseudo spray chamber that does not show beading of an aerosol; and

FIGS. 12A-C are images showing water contact angle measurements of a silica film on a silicon wafer;

FIGS. 13A-C are images showing water contact angle measurements of a silica film on a silicon wafer with extended ozone exposure;

FIG. 14 is a graph illustrating the sensitivity results for silica coated PET spray chambers (LE12) before, labeled with (1), and after, labeled with (2), cleaning in 5% Citranox (LE12-1 and LE12-2) or 5% Extran MA02 (LE12-3) solutions. LE12-4 was not cleaned between experiments;

FIG. 15 is a graph illustrating the precision results for silica coated PET spray chambers (LE12) before, labeled with (1), and after, labeled with (2), cleaning in 5% Citranox (LE12-1 and LE12-2) or 5% Extran MA02 (LE12-3) solutions. LE12-4 was not cleaned between experiments;

FIG. 16 is a graph illustrating the washout results for silica coated PET spray chambers (LE12) before, labeled with (1), and after, labeled with (2), cleaning in 5% Citranox (LE12-1 and LE12-2) or 5% Extran MA02 (LE12-3) solutions. LE12-4 was not cleaned between experiments;

FIGS. 17A-D: Optical microscopy analysis of SiO₂ coated PET coupons after exposing to 20% agua regia and 5% Extran MA02 solution. (17A) Sample LE16-C11 with 30 minutes of ozone treatment before the ALD SiO₂ deposition, 17 days with 4 cleaning cycles; (17B) Sample LE16-C11 at 47 days with 9 cleaning cycles; (17C) LE10-C1 with no ozone treatment before ALD coating, 17 days with 3 cleaning cycles; and (17D) Sample #11-C1 coated with Thierry PECVD SiO₂, exposed to 20% agua regia for only 5 days without cleaning; and

FIGS. 18A-E: Images of a silica coated PET spray chamber setup with water beading on an inner suface of the spray chamber.

### SUMMARY OF THE INVENTION

In an aspect, there is disclosed a device including a hydrophilic layer on a portion of an inner surface of a transparent polymer forming a body; wherein the hydrophilic layer includes a sulfonated inner surface of the transparent polymer, a silica, a silicon oxycarbide, an O₂ plasma treatment of the transparent polymer, or a combination thereof.

In another aspect, there is disclosed a method of making a device, comprising: forming the device by mold manufacturing or injection molding a transparent polymer; and chemically modifying a portion of an inner surface of the device to render the portion hydrophilic.

Additional features and advantages of various embodiments will be set forth, in part, in the description that follows, and will, in part, be apparent from the description, or can be learned by the practice of various embodiments. The objectives and other advantages of various embodiments will be realized and attained by means of the elements and combinations particularly pointed out in the description herein.

### DETAILED DESCRIPTION OF THE INVENTION

For simplicity and illustrative purposes, the present disclosure is described by referring mainly to an example thereof. In the following description, numerous specific details are set forth in order to provide a thorough understanding of the present disclosure. It will be readily apparent however, that the present disclosure may be practiced without limitation to these specific details. In other instances, some methods and structures have not been described in detail so as not to unnecessarily obscure the present disclosure.

Additionally, the elements depicted in the accompanying figures may include additional components and some of the components described in those figures may be removed and/or modified without departing from scopes of the present disclosure. Further, the elements depicted in the figures may not be drawn to scale and thus, the elements may have sizes and/or configurations that differ from those shown in the figures.

It is to be understood that both the foregoing general description and the following detailed description are exemplary and explanatory only, and are intended to provide an explanation of various embodiments of the present teachings. In its broad and varied embodiments, disclosed herein is a device including a hydrophilic layer on a portion of an inner surface of a transparent polymer forming a body; wherein the hydrophilic layer includes a sulfonated (or chemically modified) inner surface of the transparent polymer, a silica, a silicon oxycarbide, an O₂ plasma treatment of the transparent polymer, or a combination thereof.

The device disclosed herein can be shaped and prepared in a cost efficient manner. In this manner, the device can be disposable and/or reusable. The device can be transparent or nearly transparent to enable visualization of the contents of device and a process of solution nebulization. Additionally, the device can be durable to solvents used in Inductively Coupled Plasma processes in order to increase a lifespan of the device. Solutions used in Inductively Coupled Plasma processes can be inhibited from beading on an inner surface of the device. In particular, a hydrophilic layer on a portion of the inner surface of the device can enable the fluid droplets to flatten, coalesce, and/or drain, thereby inhibiting beading. In particular, the hydrophilic layer enables the spray chamber to be hydrophilic, withstand a low pH environment, and/or to be fabricated from clear plastics in a more cost efficient manner.

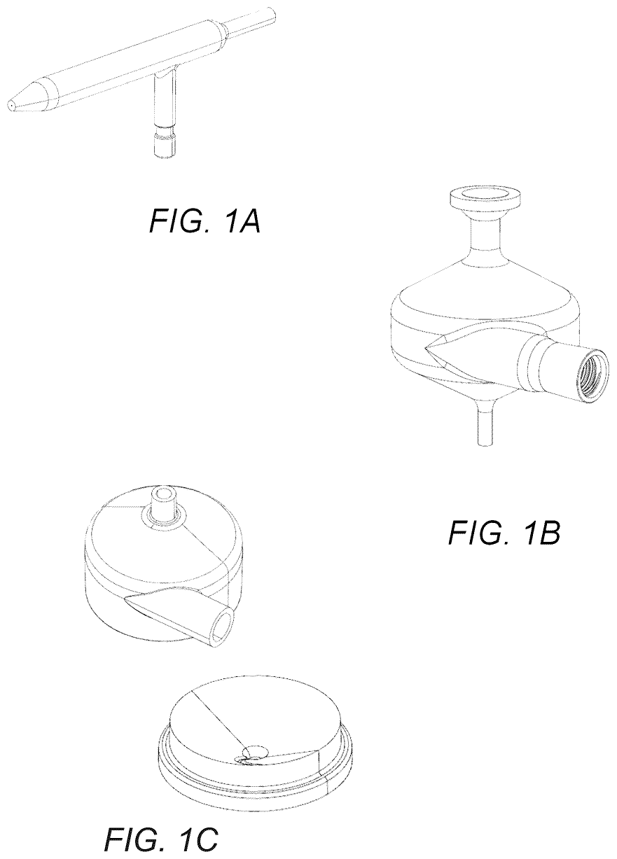

The device can be a nebulizer (as shown in FIG. 1A), a spray chamber (as shown in FIGS. 1B and 1C), or associated sample introduction vessel. In an aspect, the device can be a spray chamber including a reduced width and height in an upper chamber. The reduction in size of the upper chamber can equate to a reduced volume in the upper chamber thereby reducing the likelihood that aerosol droplets could become trapped in the upper chamber. The device can be a spray chamber including a larger volume (about 166% of an original size) in a lower chamber, which can allow larger aerosol droplets to circle out farther from an inner collection tube. The spray chamber can be a monolithic structure or can include separate connectable portions, such as first portion and a second portion.

A nebulizer can include concentric and parallel paths. A spray chamber can include cyclonic (single and double pass) and Scott types.

The device can be a body including one or more inlets and one or more outlets. The body can include an outer surface and an inner surface. The body can be formed of a transparent material. In an aspect, the transparent material can be any transparent material whose surface is or can be modified or coated to yield a hydrophilic layer. The transparent material can be a transparent polymer. Non-limiting examples of transparent polymers for use in the device include polystyrene, polyethylene terephthalate with glycol modification, polyethylene terephthalate, cyclic olefin polymers, polycarbonate, and the like. Commercially available examples of a cyclic olefin polymer include ZEONOR® 1020 and ZEONOR® 790 from Zeon Corporation, Japan. The transparent polymer can be polystyrene.

The body of the device can be formed by additive processing, such as three-dimensional printing, or injection molding capabilities. These fabrication methods can enable a variety of modifications to a body, such as a spray chamber, design, shape, and/or size.

The device, including an inner surface thereof, can be formed of the transparent polymer. A portion of the inner surface of the device can be modified, surface treated, or coated to yield a hydrophilic layer. By “a portion” is understood to mean at least 1% of the inner surface of the device, such as from about 5% to about 100%; for example from about 50% to about 99%; and as a further example, from about 75% to about 95%, including subranges and endpoints therebetween.

The hydrophilic layer can be any coating, surface treatment, and/or surface modification that can render a portion of the inner surface of the transparent polymer hydrophilic or substantially hydrophilic. For example, the hydrophilic layer can inhibit the formation of liquid beads on the portion of the inner surface of the transparent polymer. Non-limiting examples of a hydrophilic layer includes a sulfonated (carboxylated, aminated, hydroxylated or other chemical moieties that can impart a hydrophilic character) inner surface of the transparent polymer, a silica, a silicon oxycarbide, an O₂ plasma treatment of the transparent polymer, or a combination thereof.

In an aspect, the transparent polymer can be a polystyrene. The polystyrene can be chemically modified as shown below to yield a hydrophilic layer, which is a sulfonated inner surface of the transparent polymer.

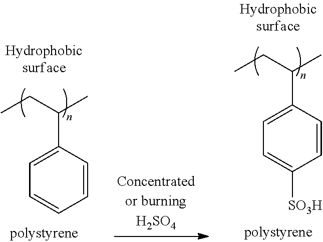

In another aspect, the device can be formed of a transparent polymer, such as polyethylene terephthalate with glycol modification or polyethylene terephthalate. A hydrophilic layer of silica or silicon oxycarbide can be deposited on a portion of an inner surface of the transparent polymer using conventional deposition processes, such as plasma enhanced chemical vapor deposition (PECVD). For example, a gas feed of oxygen:hexamethyldisiloxane (HDMSO) 3:1, as a further example, of 12:1, can be applied to the portion of the inner surface.

In another aspect, the device can be formed of a transparent polymer, such as cyclic olefin polymer. A portion of an inner surface of the transparent polymer can be surface modified using an O₂ plasma treatment to yield a hydrophilic layer on the portion of the inner surface. The O₂ plasma treatment can be performed at 500 W for 5 minutes at 400 mTorr oxygen.

The device can be a spray chamber including polyethylene glycol. A portion of an inner surface of the spray chamber can include a hydrophilic layer of silica. The hydrophilic layer of silica can be formed using atomic layer deposition. A first precursor, such as a silicon source, can be used to react to an inner surface of the body of the device to form a monolayer. A second precursor, such as an oxygen source, can be dosed in a manner to react with the monolayer to form a single fully reacted monolayer, which is a complete cycle. The cycle can be repeated several times to control a thickness of a hydrophilic layer formed of multiple fully reacted monolayers.

There is disclosed herein a method of making a device, comprising forming the device by mold manufacturing or injection molding a transparent polymer; and chemically modifying a portion of an inner surface of the device to render the portion hydrophilic. The step of forming the device can further include molding two halves of the device separately; and joining the two halves together to form the device of transparent polymer. The step of chemically modifying can further include immersing the formed device of transparent polymer into a sulfuric acid bath.

In an alternative aspect, a method of making a device can comprise forming the device by mold manufacturing or injection molding a transparent polymer; and chemically modifying a portion of a surface of the device to render the portion hydrophilic. The step of forming the device can further include molding two halves of the device separately. The step of chemically modifying can further include immersing the formed device of transparent polymer into a sulfuric acid bath. The method can include, after the step of chemically modifying, joining the two halves together to form the device.

With regard to the method steps of chemically modifying discussed above, the step of chemically modifying can include application of sulfuric acid for a period of time ranging from about 1 minute to about 1 hour, at a temperature ranging from about −5° C. to less than about 80° C. The sulfuric acid can have a concentration of at least 96%. The sulfuric acid can be a fuming sulfuric acid with from about 0.01% to about 20% free SO₃. In this manner, the step of chemical modification can include sulfonation of the portion of the inner surface of the device.

There is disclosed herein a method of making a device, comprising forming the device by mold manufacturing or injection molding a transparent polymer; and chemically modifying a portion of an inner surface of the device to render the portion hydrophilic. The step of forming the device can further include molding two halves of the device separately. The step of chemically modifying can further include plasma enhanced chemical vapor deposited silica or silicon oxycarbide of the molded two halves of the device; and immersing the coated, molded two halves of the device into a solution for chemical stability of surface hydrophilicity. The method can include, after the step of chemically modifying, joining the two halves together to form the device of coated transparent polymer.

There is disclosed herein a method of making a device, comprising forming the device by mold manufacturing or injection molding a transparent polymer; and chemically modifying a portion of a surface of the device to render the portion hydrophilic. The step of forming the device can further include molding two halves of the device separately. The step of chemically modifying can further include plasma enhanced chemical vapor deposited silica or silicon oxycarbide of the molded two halves of the device. The method can include, after the step of chemically modifying, joining the two halves together to form the device of coated transparent polymer. The device including the coated transparent polymer can be immersed into a solution for chemical stability of surface hydrophilicity.

There is disclosed herein a method of making a device, comprising forming the device by mold manufacturing or injection molding a transparent polymer; and chemically modifying a portion of a surface of the device to render the portion hydrophilic. The step of forming the device can further include molding two halves of the device separately. The step of chemically modifying can further include O₂ plasma treatment of the molded two halves of the device; and immersing the coated, molded two halves of the device into a solution, such as nitric acid, or a cleaning solution. The method can include, after the step of chemically modifying, joining the two halves together to form the device of coated transparent polymer.

There is disclosed herein a method of making a device, comprising forming the device by mold manufacturing or injection molding a transparent polymer; and chemically modifying a portion of a surface of the device to render the portion hydrophilic. The step of forming the device can further include molding two halves of the device separately. The step of chemically modifying can further include O₂ plasma treatment of the molded two halves of the device. The method can include, after the step of chemically modifying, joining the two halves together to form the device of coated transparent polymer. The device including the coated transparent polymer can be immersed into a solution, such as nitric acid or a cleaning solution.

A method of making a device, can also comprise, forming a device by additive processing or injection molding a transparent polymer; and providing a hydrophilic layer on a portion of an inner surface of the device. Providing for the hydrophilic layer can include reacting a first precursor, such as a silicon source, to the portion of the inner surface of the device to form a monolayer; and reacting a second precursor, such as an oxygen source, to the monolayer to form a fully reacted monolayer in a cycle. The method can include repeating the cycle one or more times to control a thickness of the hydrophilic layer.

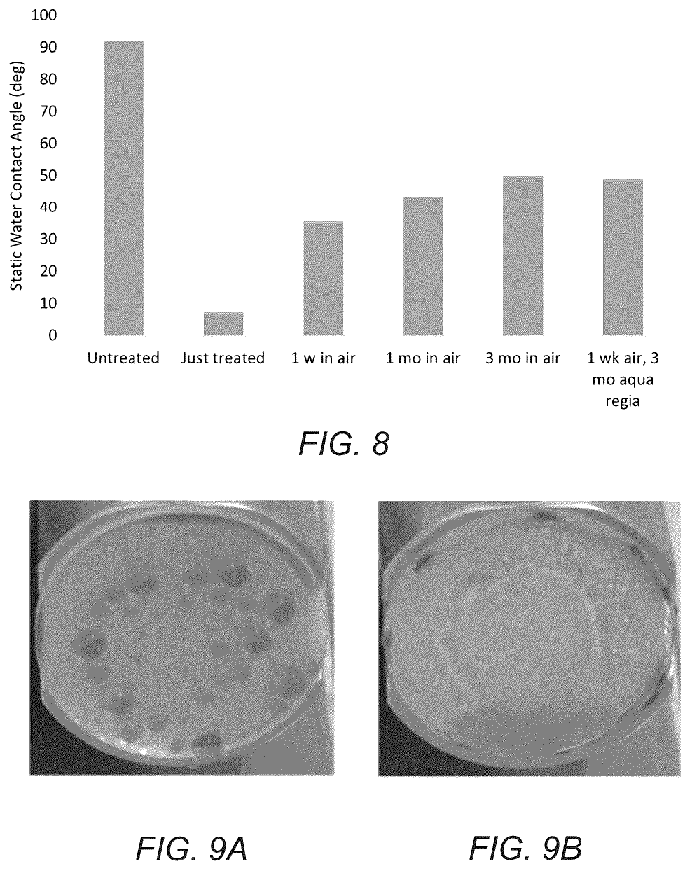

With regard to the methods of making the device described above, it should be noted that that the step of chemically modifying a portion of an inner surface of the transparent polymer does not reduce the transparency of the transparent polymer. Additionally, the hydrophobic portion (such as a hydrophilic layer) of the device can be durable over ambient room temperature (for example, ranging from about 10° C. to about 35° C., and as a further example from about 15° C. to about 30° C., including subranges, and end points therein). A person of ordinary skill in the art would understand that durability can be determined demonstrated as shown in FIG. 8. For example, in addition to the solvents, the hydrophilic portion of the device should maintain substantial hydrophilicity against storage under ambient atmosphere. (For plasma treated hydrophilicity, storage under ambient atmosphere can kill more hydrophilicity than 20% aqua regia).

For example, the hydrophilic portion of the device can be durable against solvents including 20% aqua regia, dilute hydrochloric acid, nitric acid, or combinations thereof.

### EXAMPLES

### Example 1

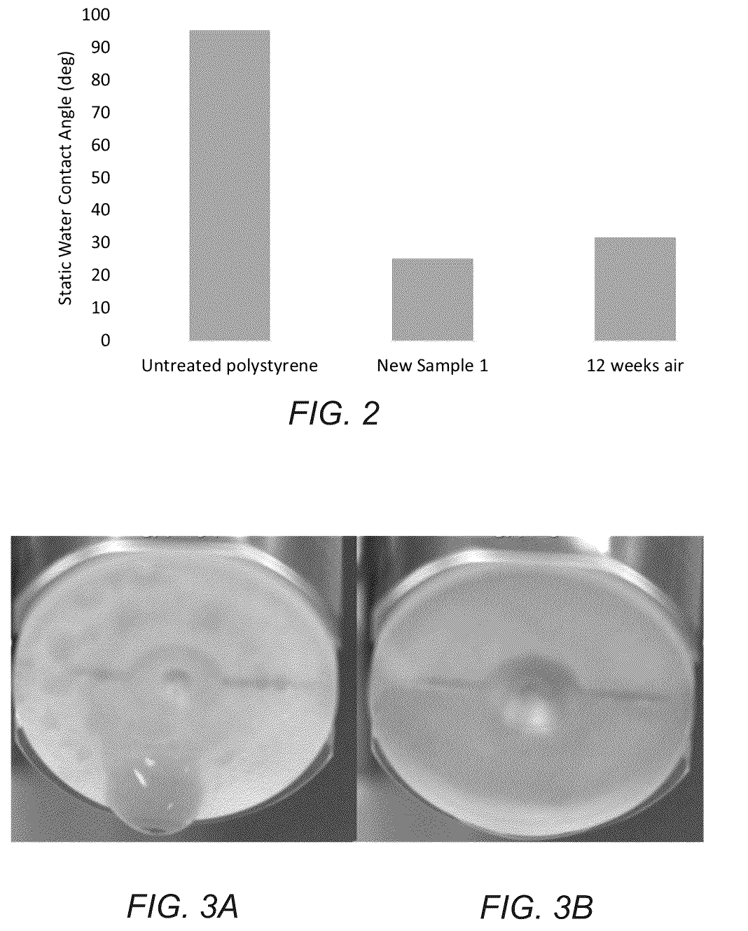

The surface hydrophilicity of a device including sulfonated polystyrene, freshly prepared (New Sample 1) and stored under ambient room temperature for 12 weeks (12 weeks air), is shown in FIG. 2. The water contact angle was analyzed on a KROSS DSA100W drop shape analyzer. The surface of interest was elevated to receive a droplet of 2.6 μL of deionized water from the tip of the syringe needle. A photo was taken by the instrument, from the image the contact angle between the water droplet and the surface was analyzed by KROSS ADVANCE software. The appearance and mass of the sample did not change over the stored time.

The coupon provided a flat surface for characterizing the extent or depth of any surface modifications and was representative of the coating on the inner surfaces of the device, such as a nebulizer or a spray chamber.

### Example 2

The performance of untreated (left) and chemically modified (right) transparent polymer (polystyrene) in a pseudo spray chamber was tested. As shown in FIG. 3A, application of a fine aerosol caused beading on the untreated transparent polymer, whereas the chemically modified (sulfonation) transparent polymer, as shown in FIG. 3B, had sufficient surface hydrophilicity to fully wet the surface and inhibit any water bead formation.

### Example 3

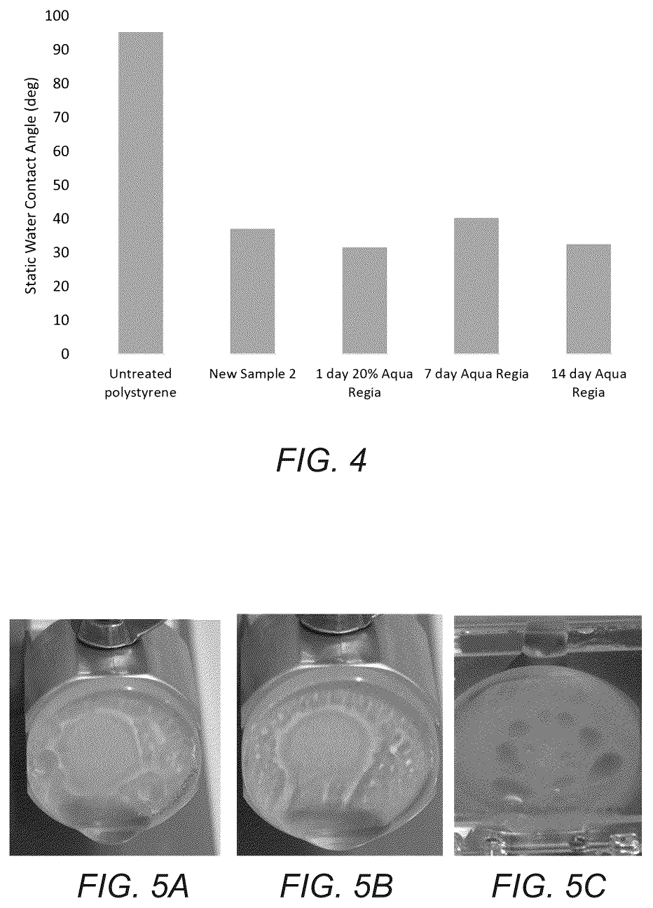

The surface hydrophilicity of sulfonated polystyrene, freshly prepared (New Sample 2) was stored with continuous 20% aqua regia contact for up to 14 days, as shown in FIG. 4. The appearance and mass of the sample did not change over the period of time.

### Comparative Example 1

An actual plasma enhanced chemical vapor deposition (PECVD) silica coating exhibited insufficient hydrophilicity, which led to beading of a sprayed solution in the device and having a static water contact angle of about 45° to about 65°. If a silicon oxycarbide was targeted, the hydrophobicity issue was worse (e.g., having a static water contact angle of about 60° to about 1100).

### Example 4

A device containing a transparent polymer with an activated high surface hydrophilicity silica (or silicon oxycarbide) was formed. Thierry plasma using a kilohertz plasma PECVD tool with a gas feed of hexamethyldisiloxane:O₂=3:1 was used. The coating was characterized by X-ray photoelectron spectroscopy (XPS) with ˜1-2%, ˜32% Si, ˜65% O. The surface (<20 nm) was found to be ˜19% C, ˜24% Si, ˜57% O.

The device exhibited a static water contact angle of 60°-70° following PECVD deposition of the silica. It was then immersed in a solution containing 2% commercially available “RBS-25 solution” in deionized water (20-30 minutes) to activate the hydrophilicity followed by deionized water rinsing. The device was characterized by static water contact angle of ˜15°. XPS characterization showed little change on the elemental composition of the surface by RBS solution treatment.

Additionally, the PECVD silica (or silicon oxycarbide) coated transparent polymer was durable against continuous 20% aqua regia contact. In particular, a coated coupon was contacted with ICP-OES solvent for 25 days. FIGS. 5A-C illustrate the following: 5A is 20% aqua regia, 5B is A-solv (kerosene), followed by sonication in 5% Triton X-100 for 5 days (sprayed water test), and 5C is an example of beading water on a plastic surface without treatment. As shown, the transparent polymer with the hydrophilic layer was durable against continuous A-solv contact and 20% aqua regia. Additionally, A-solv increased the static water contact angle to ˜56° (as shown in FIG. 5B) even with thorough rinsing with hexane. The spray of water on the surface led to a continuous water film rather than beading, which was characterized by static water contact angle of receded droplet being ˜14°. The hydrophilicity lost from A-solv contact did not affect the non-beading property, and the lost hydrophilicity was restored with sonication in 5% commercially available “Extran MA02” solution for 30 minutes or 2% Triton X-100 for 3 hours.

### Example 5

ICP-OES spray chambers are often cleaned with aggressive (highly alkaline and/or oxidative) cleaning solution under sonication. Many inorganic oxide-coated plastics fail under this condition. The coated transparent polymer was preserved for tens of cleaning cycles under non- or low-etching cleaning methods.

A PECVD silica coated transparent polymer (polyethylene terephthalate with glycol modification—PETG) coupon was contacted with ICP-OES solvent followed by sonication in spray chamber cleaning solutions. The number of equivalent cleaning cycles were calculated by durability divided by the time required to erase the hydrophobic effect of A-solv contact (30 minutes for Extran MA02, 3 hours for Triton X-100. The results are shown in Table 1. The results indicated that at least tens of cleaning cycles can be performed before failure of the hydrophilicity.

TABLE 1

| Solvent | Cleaning | Durability | Equivalent |
|---|---|---|---|
| Contact | Solution | (days) | Cleaning Cycle |
| None | 5% Extran MA02 | >2 | >96 |
| None | 5% Triton X-100 | >9 | >72 |
| A-solv 25 days | 5% Triton X-100 | >5 | >40 |
| 20% Aqua Regia | 5% Triton X-100 | >5 | >40 |
| 25 days | | | |

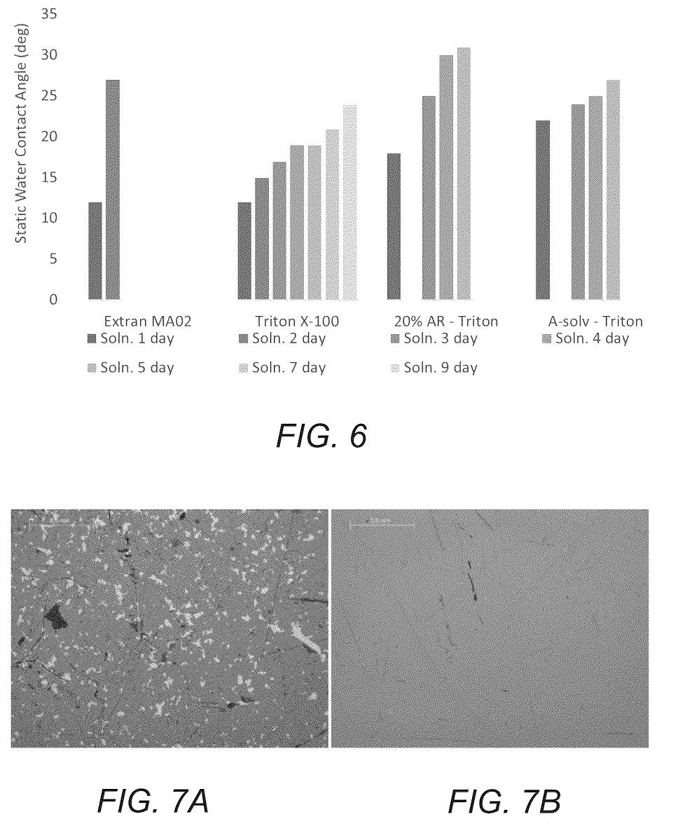

FIG. 6 shows the static water contact angle measurement of the PECVD silica coated PETG coupon with ICP-OES solvents followed by sonication in spray chamber cleaning solutions. The sonic cleaning induced damage on the surface, if any, appeared as scattered loss of coating (appeared as lighter under optical microscopy (OM) after a period of cleaning experiment) gradually emerging with the sonication time, as shown in FIGS. 7A-7B. The loss of coating did not show significant preference at surface defect of substrate (existed before coating, appeared as black lines under OM) or scratch/crack of coating (few were observed, appears as lighter area under OM) existing before the start of cleaning, suggesting the robustness of this coating method with non-perfect substrate and storage/shipment/usage conditions. Even with the damage of the coating induced by prolonged sonic cleaning on and increased static water contact angle, with the “static water contact angle of receded droplet” being ˜16°, sprayed water on the surface still led to a continuous water film rather than beading, as shown in FIGS. 5A-B.

FIGS. 7A-B are optical microscopy images of the PECVD silica coated PETG coupon with ICP-OES solvents followed by sonication in spray chamber cleaning solutions. FIG. 7A is the PECVD silica coated PETG coupon contacted for 25 days with 20% aqua regia, followed by sonication in 5% Triton X-100 for 5 days. FIG. 7B is the PECVD silica coated PETG coupon contacted for 25 days with A-solv, followed by sonication in 5% Triton X-100 for 5 days.

### Example A

An O₂ plasma treatment was applied using a kilohertz plasma PECVD tool with a gas feed of oxygen:hexamethyldisiloxane=12:1 was used. 20 minutes in activation solution a hydrophilic surface was present.

### Example 6

500 W, 5 minutes at 400 m Torr oxygen provided performance for the O₂ plasma treatment of a cyclic olefin polymer. For the chemical stabilization of the surface hydrophilicity, the surface was immersed in 10% HNO₃ solution for 1-2 hours at room temperature, followed by rinsing with water and air drying was provided for performance. A concentrated (e.g., 70% nitric acid) or a stronger oxidizer (e.g., 5% ammonium persulfate) did not provide performance. Without the chemical stabilization, the surface reverted to its characteristics prior to the O₂ plasma treatment within 1-4 weeks of storage in air and ambient conditions. As shown in FIG. 8, the surface hydrophilicity of a cyclic olefin polymer, freshly treated with O₂ plasma, followed by 10% aqueous nitric acid, then stored under air (ambient room temperature), as well as continuous aqua regia contact for up to 12 weeks was measured. The data show that the appearance and mass of the sample did not change over the storage or continuous aqua regia contact.

The performance of untreated (FIG. 9A) and O₂ plasma treated followed by 12 weeks of air storage (FIG. 9B) a cyclic olefin polymer in a pseudo spray chamber was studied. A fine mist caused beading on the untreated cyclic olefin polymer coupon, whereas the O₂ plasma treated cyclic olefin polymer coupon had a sufficient hydrophilic coating to fully wet the surface and inhibit any bead formation. The chemical stabilization with the nitric acid solution preserved the hydrophilic coating against storage under ambient air.

### Example 7

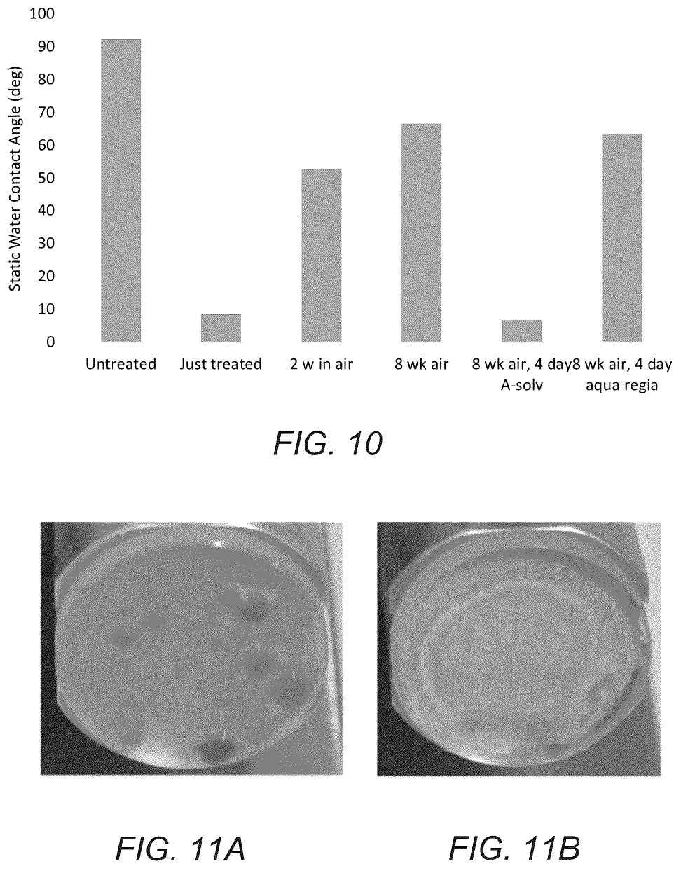

As shown in FIG. 10, the surface hydrophilicity of polyethylene terephthalate with glycol modification, freshly prepared (O₂ plasma then 10% nitric acid) and stored in air for up to 8 weeks, and with 20% aqua regia and A-solv (kerosene) contact for up to 4 days was measured. The appearance and mass of the sample did not change over the storage, continuous aqua regia or A-solv contact.

The performance of untreated (FIG. 11A) and O₂ plasma treated followed by 8 weeks of air storage (FIG. 11B) a polyethylene terephthalate with glycol modification in a pseudo spray chamber was studied. A fine mist caused beading on the untreated polyethylene terephthalate with glycol modification coupon, whereas the O₂ plasma treated polyethylene terephthalate with glycol modification coupon had a sufficient hydrophilic coating to fully wet the surface and inhibit any bead formation. The chemical stabilization with the nitric acid solution preserved the hydrophilic coating against storage under ambient air.

### Example 8

The hydrophilic layer of SiO₂ (i.e., a coating) was made using a vapor phase deposition process, such as Atomic Layer Deposition (ALD). ALD is a vapor deposition method used to make thin films in a sequential layer-by-layer growth method. For ALD, parts and substrates are first put under vacuum and/or a chamber of inert atmosphere. To make a hydrophilic layer of SiO₂ using ALD, a 1st precursor vapor was exposed into the vacuum chamber with the substrates to be coated. The first silicon source precursor, Orthrus obtained from Air Liquide. This precursor allowed for a low temperature SiO₂ coating to be made, which is beneficial for coating plastics that would otherwise deform or melt in SiO₂ ALD recipes that require higher temperatures. This precursor was used as received and heated in a dual stage heating jacket set at 50° C. on the lower stage and 55° C. on the higher stage.

This precursor reacted to the substrate surface, but not itself, thus forming a monolayer of precursor that was bound to the substrate. Excess or unreacted vapors were purged away with an inert gas and a 2nd precursor was dosed into the chamber. This 2nd precursor, or co-reactant, was chosen to react with the already-bound 1st precursor, but not to itself. Ozone, O₃, was used as the oxygen source precursor. Ozone was synthesized from oxygen using a Savannah ozone generator attached to the ALD vacuum chamber tool (Savannah S300, Veeco). The chamber temperature during the ALD was performed at 50-70° C.

After exposure to the ozone, excess or unreacted vapors were purged from the chamber resulting in a single fully reacted monolayer on all surfaces within the vacuum chamber, and thus completing one full ‘cycle’ of ALD. Each cycle of ALD resulted in a new reacted monolayer on the substrate surface and was used to control the thickness of film deposited. Because ALD is a vapor process with precursors separated by inert gas purging steps, thin films of very even thicknesses (high conformality) can be made into very narrow trenches, bores, or other complicated substrate features, such as the insides of spray chambers.

Prior to the SiO₂ deposition, the plastic spray chamber substrates were loaded into the ALD chamber and allowed a 1-5 hour pump-down and warmup time to remove moisture and gas from the spray chamber samples. After warmup, ozone was pulsed into the chamber to activate the plastic surface, enabling the SiO₂ precursors to chemically adhere. This was done with a 0.2 s pulse of ozone (˜100 mg/L concentration) into the non-purging ALD chamber and held for 5 minutes before purging with N₂ for 20 s. This sequence was repeated 12 or more times for a total of 60 minutes of ozone pretreatment of the plastic.

After the ozone pretreatment ALD cycling began as follows: the first step of the cycle was a 0.2 s pulse of the Orthrus precursor into the vacuum chamber without any active pumping. The precursor remained in the chamber to react for 90 seconds and was then purged out with high nitrogen flow and pumping for 65 seconds. Once the chamber was purged, ozone (˜100 mg/L concentration) was dosed into the chamber for 0.2 seconds with no active pumping. The ozone remained in the chamber to react for 300 seconds and was purged away with high nitrogen flow and active pumping for 75 seconds. This sequence was repeated for approximately 225 cycles, resulting in 50-55 nm of film deposition on the substrates, as measured by ellipsometry on silicon wafer samples. Note the long exposure time for ozone was used to maximize the combustion reaction of the growing surface, which can be difficult at these relatively low temperatures, resulting in a better SiO₂ film.

Once the SiO₂ film deposition was completed, a final ozone activation step was performed to ensure the SiO₂ film was fully reacted and maximized the hydrophilicity of the final film. This was done by dosing ozone for a 0.2 second pulse without active pumping and held for 5 minutes. After purging for 20 seconds, these steps were repeated for 24 or more cycles totaling 120 or more minutes of ozone exposure. The full recipe took approximately 48 hours to complete.

### Example 9—Silica Water Contact Angle

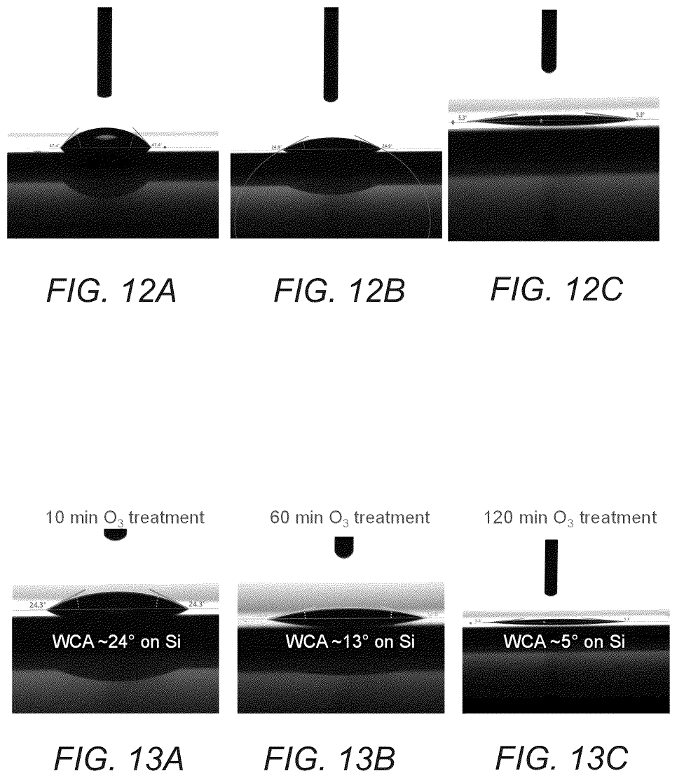

After the deposition process, sample substrates of silicon run alongside the spray chambers during the deposition were used to test the SiO₂ deposited film thickness using ellipsometry. These substrates along with sample plastic coupons were also used to test the hydrophilicity of the final film using water contact angle (WCA) measurement, as shown in FIGS. 12A-C. In the images, hydrophilicity was increased (decrease in WCA) with modifications of the ALD recipe. Longer ozone exposure times and the extended 120 minute ozone dose at the end of the deposition enabled the final film to become fully hydrophilic. FIGS. 13A-C show how extended ozone exposure at the end of the deposition reduced the WCA.

### Example 10—Silica Coated PET Spray Chamber Functional Results

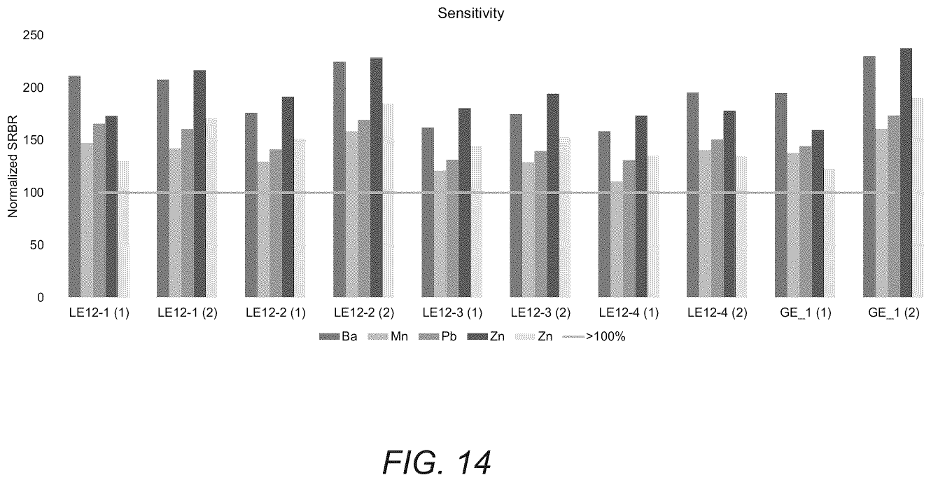

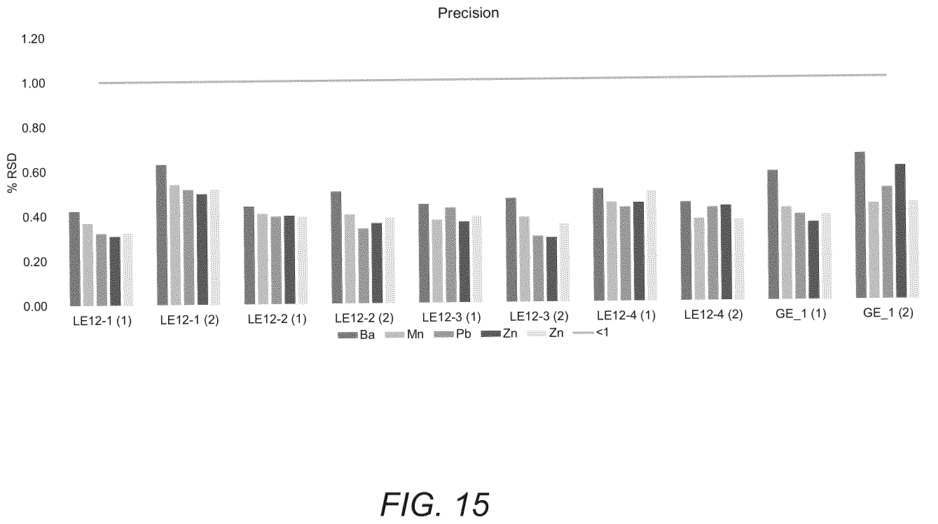

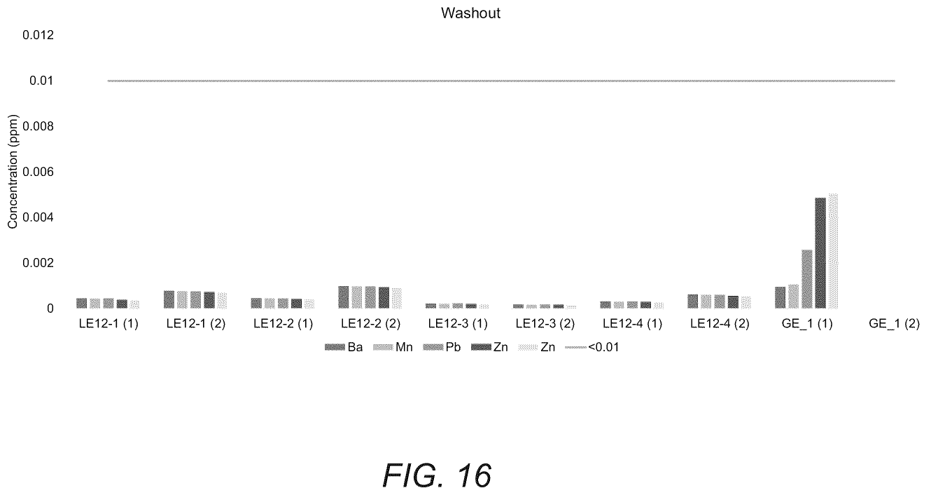

Preliminary experiments of SiO₂ coated PET spray chambers with ICP-OES have shown the sensitivity, precision, and washout tests were within a passing metric when the spray chambers were cleaned in a 2% RBS-25 solution. FIGS. 14-16 shows the results of the sensitivity (FIG. 14), precision (FIG. 15), and washout (FIG. 16) tests performed across 4 separate SiO₂ coated PET spray chambers and one glass cyclonic spray chamber. The 4 SiO₂ coated PET spray chambers labeled LE12-1 through LE12-4 were initially tested after cleaning the spray chambers in a 2% RBS-25 solution for one minute, labeled (1). After the initial test, the SiO₂ coated PET spray chambers underwent a separate cleaning step and retested. The cleaning step was soaking the spray chamber in a solution of 5% Citranox (for sample LE12-1 and LE12-2) or a 5% solution of Extran MA02 (sample LE12-3) for 1 hour then rinsed with DI water and resubmerged into the soaking solution for a total of 5 cycles. LE12-4 was a control that was not cleaned in any solution. After the cleaning, the results of the retested spray chambers were labeled with (2). As seen in the plots, all the SiO₂ coated PET spray chambers passed the 100% SRBR (signal-to-root-background ratio) sensitivity test and were less than 1% RSD (Relative Standard Deviation) in the precision test before and after cleaning. Likewise, all the spray chambers passed the 0.01 ppm metric for a washout test. The sample labeled GE was the glass cyclonic spray chamber used as a reference.

As noted, the experiments in FIGS. 14-16 were done with RBS-25 cleaned spray chambers, which helped to clean and activate the SiO₂ coated surface. RBS-25 contains NaOH and NaOCl, making a very basic solution (pH 13.6) which acts to clean and etch the SiO₂ surface making it hydrophilic. Additionally, this solution can also increase the amount of surface silanol groups which also increase hydrophilicity. SiO₂ coated PET spray chambers that have been tested without the RBS-25 solution cleaning have not performed as well as the RBS cleaned spray chambers, such as the washout tests.

### Example 11—Silica Coated PET Spray Chamber Stability Tests

The durability of the SiO₂ coated spray chambers against strong acid (ICP-OES solvent) and cleaning solution is a metric for users. Two separate tests were developed to evaluate the adhesion, cracking, and hydrophilicity of the SiO₂ coating of the film after exposure to acidic conditions similar to the ICP-OES environment as well as cleaning solutions that could be used to reactivate the initial working conditions of the spray chambers.

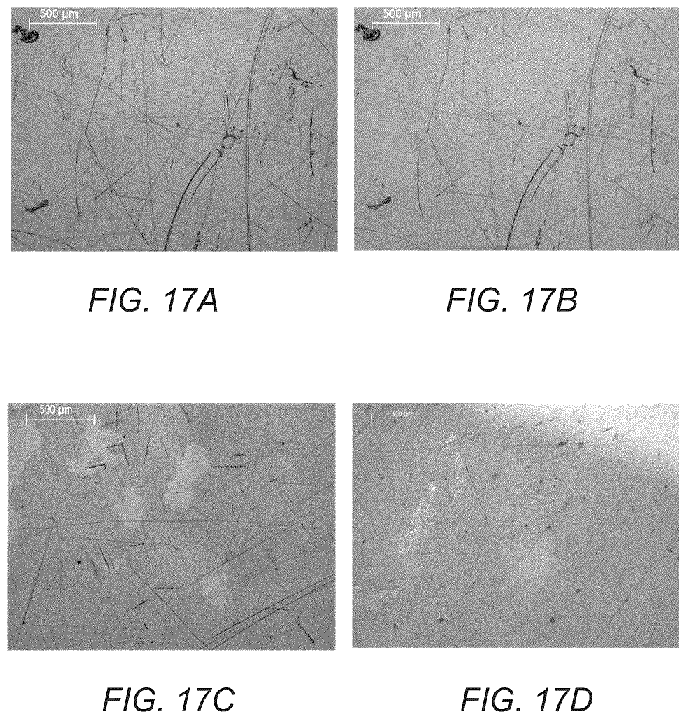

The durability test was done using PET coupon samples that were ALD SiO₂ coated alongside the PET spray chambers. The PET coupons allowed for easier optical microscopy to evaluate the stability of the coating. In these experiments, PET coupons were submerged into a solution of 5% HNO₃ or 20% aqua regia with light stirring. Samples were stirred in the solution for a given number of days then taken out and cleaned for 90+ minutes in either 5% Extran MA0₂ or 15% Citranox solutions before optical microscopy imaging. Shown in FIGS. 17A-D are the results of coupons that underwent 20% agua regia stirring and cycles of cleaning in 5% Extran MA02 solution. In the images, the large dark scratches are from the plastic and not part of the film. In FIGS. 17A and 17B, sample LE16-C11 only shows the deep dark scratches, indicating the film was still intact. In FIG. 17C, sample LE10-C1, however, shows microscopic cracking throughout the surface, indicating the thin film was cracking and potentially delaminating from the plastic surface. The SiO₂ film made for the LE10-C1 sample did not include an ozone pretreatment, which potentially led to weak adhesion of the film to the PET plastic, making it more vulnerable to cracking. Sample LE16-C11 had 30 minutes of ozone pre-exposure, which can activate the PET surface allowing for better chemical bonding of the SiO₂ ALD layer. The film was durable for 47 days in 20% aqua regia including 9 cycles, which was equivalent to about half year of customer usage (based on 8 hours use per business day, cleaning monthly). Compared to FIG. 17D (crack and delamination occurred at 5 days of 20% aqua regia contact and before any cleaning), the ALD coating with ozone pretreatment also has far better durability.

### Example 12—Silica Coated on an Inner Surface of PET Spray Chambers

SiO₂ coated PET spray chambers were tested using ICP-OES spraying parameters by nebulizing 5% HNO₃ (1.0 mL/min) into the spray chamber from a peristaltic pump along with house N₂ (0.7 L/min). The spray chamber was placed at the bottom of an acid drain sink and blue food-colored water went through for a visual analysis of water beading on the spray chamber inner surface. For safety concerns, the spray chamber was covered with a beaker to trap the nebulized droplets from escaping the sink, and the sink was completely covered with a transparent acrylic cover when not being inspected.

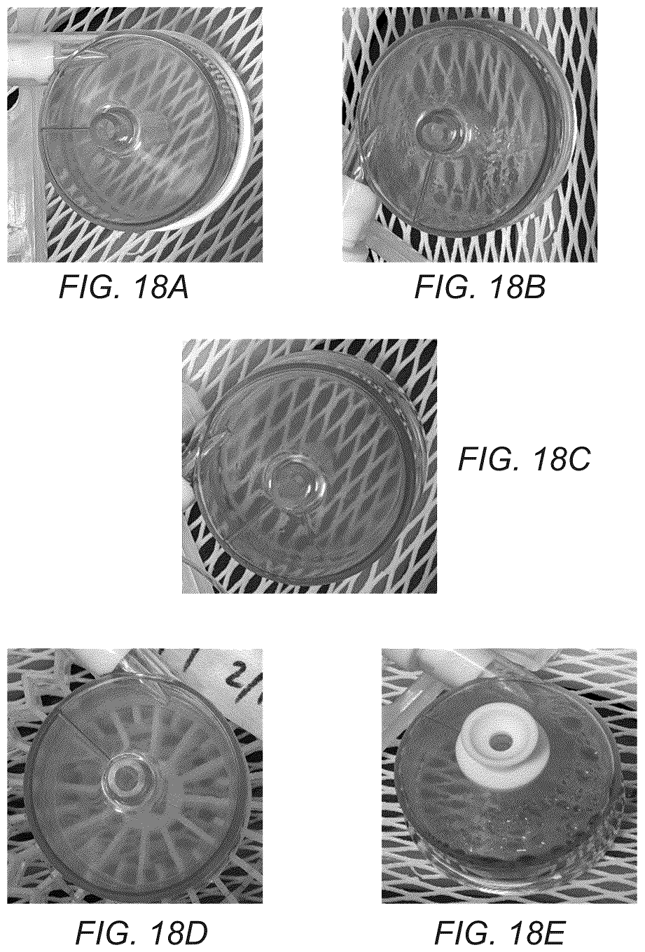

Using this spray chamber setup, long-term testing was done in conditions similar to real use. After spraying 5% HNO₃ for several days through the nebulizer and SiO₂ coated PET spray chamber setup, visual inspection of water beading done by temporarily switching to a blue colored water solution. The results are shown in FIGS. 18A-E. FIG. 18A shows no visual beading of the blue water droplets after 7 days of HNO₃ flow and 2 cycles of cleaning in 15% Citranox solution. The same was tested again after 10 days sitting in ambient air conditions, and slight beading starts to appear on the inner surface (FIG. 18B). The hydrophilicity was restored after 5% Extran MA02 cleaning (FIG. 18C). The hydrophilicity was maintained for a total of at least 46 days of HNO₃ spraying and 8 15% Citranox cleaning cycles (which is equivalent to about half year of customer usage) (FIG. 18C). For comparison, another spray chamber that lost most of its hydrophilicity is shown in FIG. 18E, where very large droplets can be seen. Spray chambers that exhibit severe beading, such as shown in FIG. 18E, generally give reduced sensitivity, precision and washout results as compared to those with a hydrophilic layer.

From the foregoing description, those skilled in the art can appreciate that the present teachings can be implemented in a variety of forms. Therefore, while these teachings have been described in connection with particular embodiments and examples thereof, the true scope of the present teachings should not be so limited. Various changes and modifications can be made without departing from the scope of the teachings herein.

This scope disclosure is to be broadly construed. It is intended that this disclosure disclose equivalents, means, systems and methods to achieve the devices, activities and mechanical actions disclosed herein. For each device, article, method, mean, mechanical element or mechanism disclosed, it is intended that this disclosure also encompass in its disclosure and teaches equivalents, means, systems and methods for practicing the many aspects, mechanisms and devices disclosed herein. The claims of this application are likewise to be broadly construed. The description of the inventions herein in their many embodiments is merely exemplary in nature and, thus, variations that do not depart from the gist of the invention are intended to be within the scope of the invention. Such variations are not to be regarded as a departure from the spirit and scope of the invention.

What is claimed is:

1. A device, comprising:
a hydrophilic layer on a portion of an inner surface of a transparent polymer forming a body,
wherein the hydrophilic layer includes a sulfonated inner surface of the transparent polymer, a silica, a silicon oxycarbide, an O₂ plasma treatment of the transparent polymer, or a combination thereof.

2. The device of claim 1, wherein the transparent polymer is polystyrene.

3. The device of claim 1, wherein the hydrophilic layer is the sulfonated inner surface of the transparent polymer.

4. The device of claim 1, wherein the device is disposable.

5. The device of claim 1, wherein the hydrophilic layer is silica or silicon oxycarbide.

6. The device of claim 1, wherein the transparent polymer is polyethylene terephthalate with glycol modification or polyethylene terephthalate.

7. The device of claim 1, wherein the transparent polymer is a cyclic olefin polymer.

8. The device of claim 1, wherein the hydrophilic layer is an O₂ plasma treatment of the transparent polymer.

9. The device of claim 1, wherein the device is a spray chamber.

10. The device of claim 1, wherein the device is a nebulizer.

11. A method of making a device, comprising:
forming the device by mold manufacturing or injection molding a transparent polymer; and
chemically modifying a portion of an inner surface of the device to render the portion hydrophilic.

12. The method of claim 11, wherein the step of chemical modification does not reduce transparency of the transparent polymer.

13. The method of claim 11, wherein the step of chemical modification includes sulfonation of the portion of the inner surface of the device.

14. The method of claim 11, wherein the hydrophilic portion of the device is durable over ambient room temperature.

15. The method of claim 11, wherein the hydrophilic portion of the device is durable against solvents including 20% aqua regia, dilute hydrochloric acid, nitric acid, or combinations thereof.

16. The method of claim 11, wherein the step of forming the device, further comprises,
molding two halves of the device separately; and
joining the two halves together to form the device of transparent polymer.

17. The method of claim 11, wherein the step of chemically modifying, further comprises,
immersing the formed device of transparent polymer into a sulfuric acid bath.

18. The method of claim 11, wherein the step of forming the device, includes molding two halves of the device separately; and
after the step of chemically modifying, the method further comprises, joining the two halves together to form the device.

19. The method of claim 11, wherein the step of chemically modifying includes application of sulfuric acid for a period of time ranging from about 1 minute to about 1 hour, at a temperature ranging from about −5° C. to less than about 80° C.

20. The method of claim 19, wherein the sulfuric acid has a concentration of at least 96%.
